(19) United States
(12) Patent Application Publication
(10) Pub. No.: US 2012/0105133 A1
(43) Pub. Date: May 3, 2012

(54) INPUT DEVICE

(76) Inventors: Young Wook Kim, Seoul (KR); Ji Hoon Kim, Yongin-si (KR); Sung Won Kim, Seoul (KR); Young Moon Sonn, Seoul (KR)

(21) Appl. No.: 13/281,706

(22) Filed: Oct. 26, 2011

(30) Foreign Application Priority Data
Oct. 29, 2010 (KR) 10-2010-0106566
Feb. 22, 2011 (KR) 10-2011-0015629

(51) Int. Cl. H03K 17/96

(52) U.S. Cl. 327/517

(57) ABSTRACT

An input device includes a window, a transparent electrode disposed on each of a plurality of areas under the window, and a wire connected to the transparent electrode. The transparent electrode includes first and second electrodes. Each of the first and second electrodes includes at least two or more electrode parts and a connection part connecting the at least two or more electrode parts to each other. At least one electrode part of the first electrode is disposed between the electrode parts of the second electrode. The wire is connected to each of the first and second electrodes to extend outside an area which does not contact the other area contacting an area on which the transparent electrode is disposed.

### CROSS-REFERENCE TO RELATED APPLICATIONS

The present application claims priority under 35 U.S.C. §119 to Korean Patent Application No. 10-2010-0106566, filed on Oct. 29, 2010, and Korean Patent Application No. 10-2011-0015629, filed on Feb. 22, 2011, which are each hereby incorporated by reference in their respective entireties.

### BACKGROUND

Personal computers, portable transmission equipments, or other information processing devices perform text and graphic processing using various input devices such as a keyboard and a mouse. Recently, touch panels are being widely used as the input devices. Such a touch panel can input various commands while watching a displayed screen without using an input device such as a separate button. The touch panel detects a user's contact position on the displayed screen. Then, the touch panel performs overall controls of electronics including a control of the displayed screen based on the input data with the detected contact position.

In the touch panel, the current trend is toward a technology in which an input position of the touch panel is detected by a capacitive overlay. According to the capacitive overlay, when a user's finger contacts the touch panel, a fine current flows by capacitance to detect a contact position through the current. Here, the user's finger may contact a dielectric layer disposed on an electrode to generate the capacitance.

### SUMMARY

Embodiments are related to an input device having a new structure.

Embodiments are related to an input device configured to precisely detect a user's input position.

Embodiments are related to a thin input device that utilizes a capacitive touch panel.

Embodiments are related to a thin input device panel having a reduced overall manufacturing cost.

In accordance with embodiments, an input device may include at least one of the following: a window; a transparent electrode disposed on and/or over each of a plurality of areas under the window; and a wire connected to the transparent electrode, the transparent electrode including first and second electrodes, each of the first and second electrodes including at least two or more electrode parts and a connection part connecting the at least two or more electrode parts to each other, and at least one electrode part of the first electrode being disposed between the electrode parts of the second electrode, and the wire being connected to each of the first and second electrodes to extend outside an area which does not contact the other area contacting an area on and/or over which the transparent electrode is disposed.

In accordance with embodiments, an input device may include at least one of the following: a window; a transparent electrode disposed on and/or over each of a plurality of areas under the window; and a wire connected to the transparent electrode, the transparent electrode including first and second electrodes, each of the first and second electrodes including at least three or more electrode parts and a connection part connecting the at least three or more electrode parts to one another, at least one electrode part of the first electrode being disposed between the electrodes of the second electrode, and at least two electrode parts of the first electrode being disposed outside an area between the electrode parts of the second electrode, and the wire being connected to each of the first and second electrodes to extend outside an area which does not contact the other area contacting an area on which the transparent electrode is disposed.

In accordance with embodiments, an input device may include at least one of the following: a window; first and second transparent electrodes under the window; and a wire connected to each of the first and second transparent electrodes, the window including long sides in a first direction and a second direction opposite to the first direction, and short sides in a third direction and a fourth direction opposite to the third direction, the first transparent electrode including a plurality of unit transparent electrodes in the first direction with respect to a virtual line parallel to the long sides, and the second transparent electrode including a plurality of unit transparent electrodes in the second direction with respect to the virtual line parallel to the long sides, each of the unit transparent electrodes of the first transparent electrode including a first electrode in the first direction and a second electrode between the first electrode and the second transparent electrode, each of the unit transparent electrodes of the second transparent electrode including a first electrode in the second direction and a second electrode between the first electrode and the first transparent electrode, and the first and second electrodes of the first transparent electrode being dislocated in the third or fourth direction and the first and second electrodes of the second transparent electrode are dislocated in the third or fourth direction.

### DRAWINGS

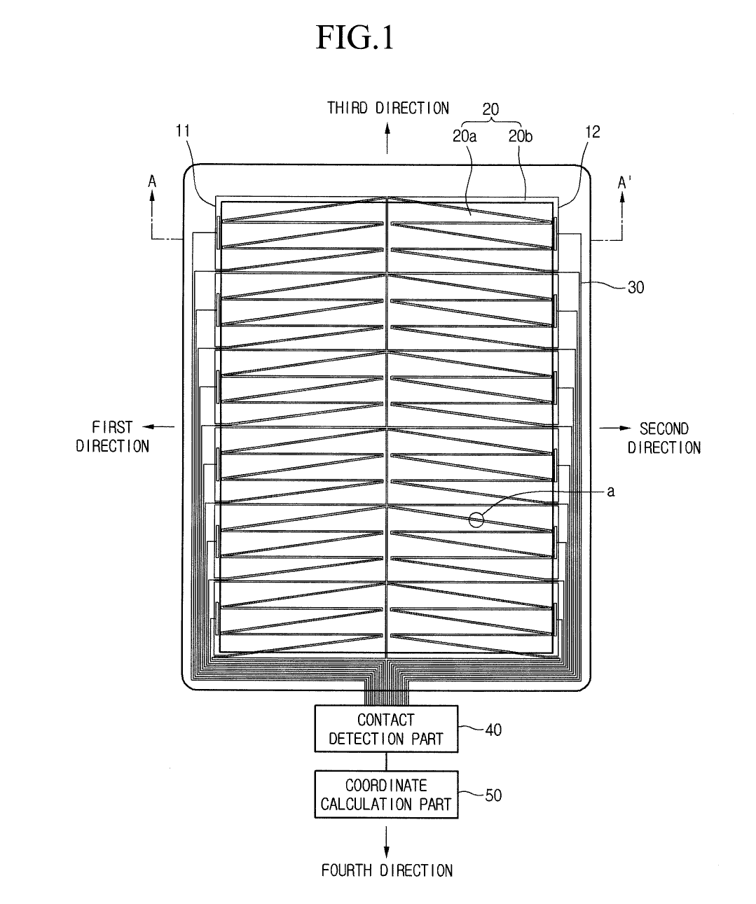

Example FIG. 1 illustrates a plan view of an input device in accordance with embodiments.

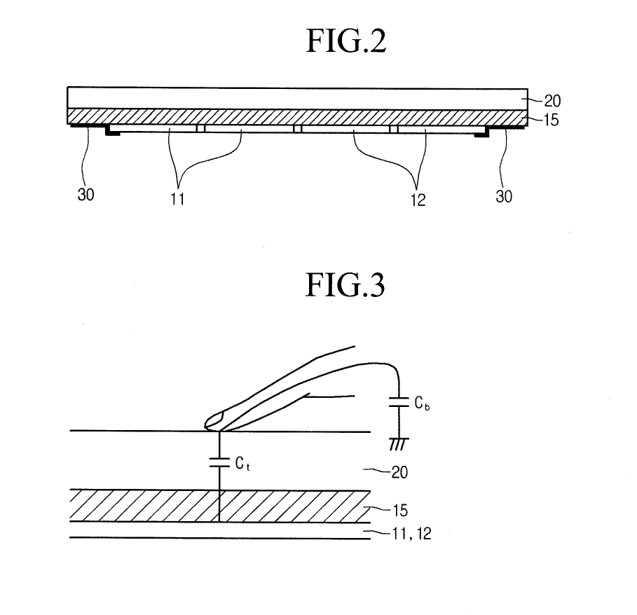

Example FIG. 2 illustrates a sectional view taken along line A-A′ of example FIG. 1.

Example FIG. 3 illustrates a view of an operation principle of the input device in accordance with embodiments.

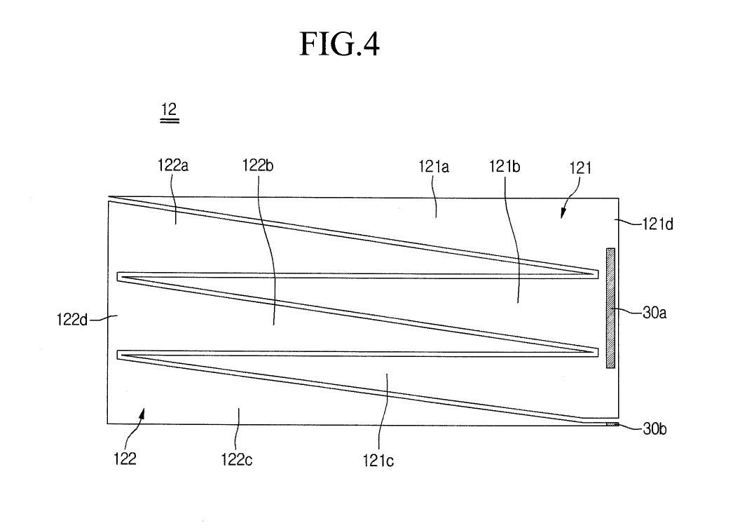

Example FIG. 4 illustrates a view of a unit electrode of a transparent electrode in the input device in accordance with embodiments.

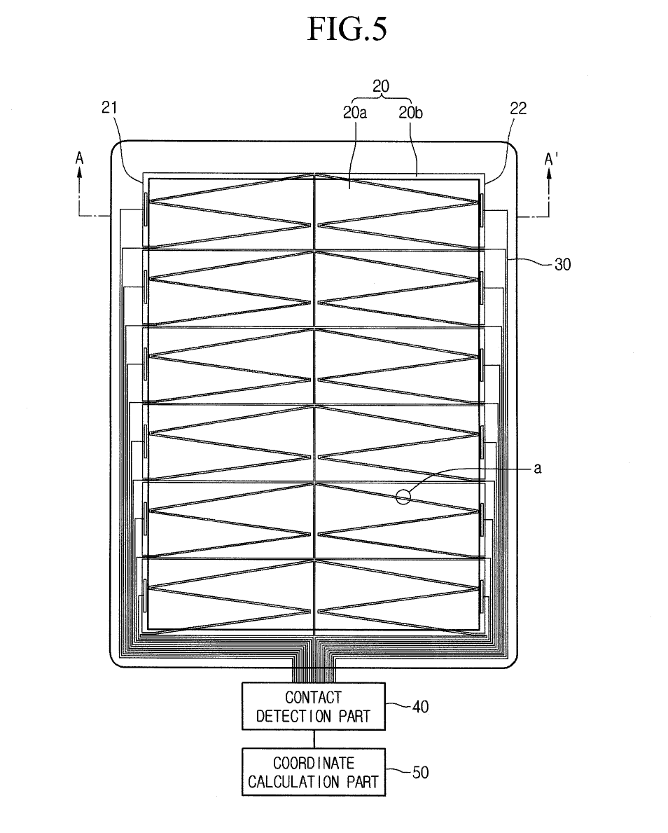

Example FIG. 5 illustrates a plan view of an input device in accordance with embodiments.

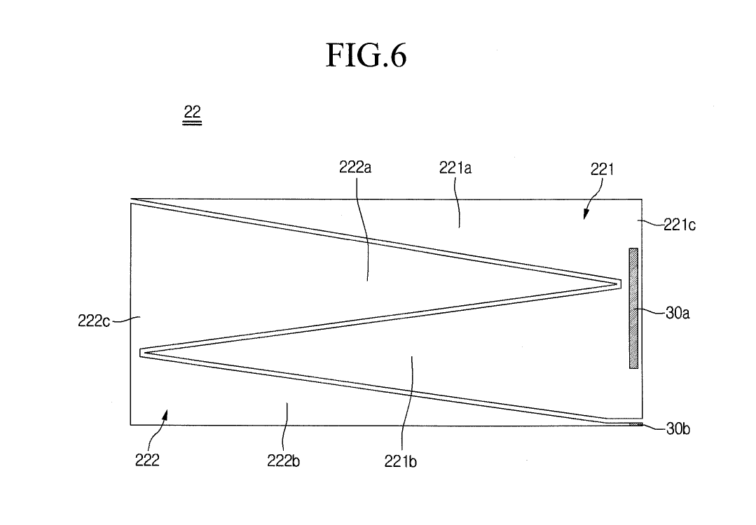

Example FIG. 6 illustrates a view of a unit electrode of a transparent electrode in the input device in accordance with embodiments.

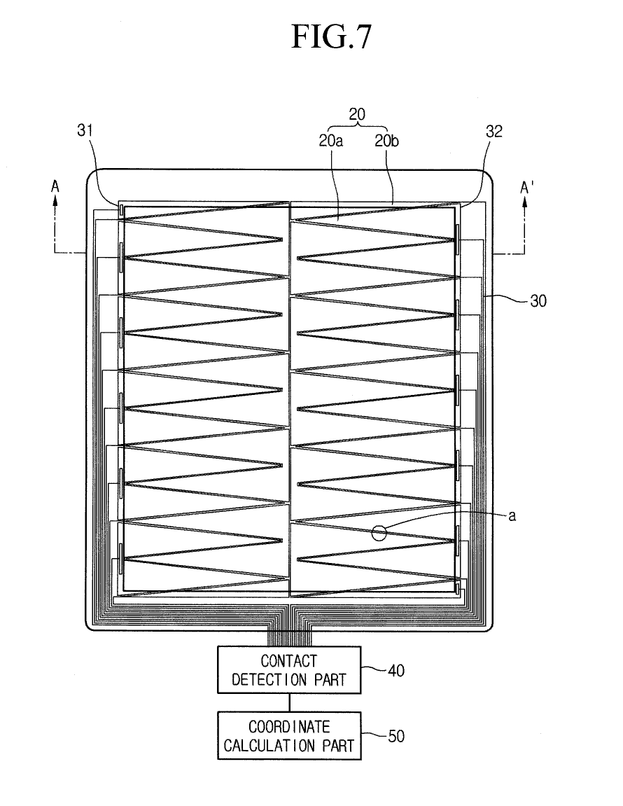

Example FIG. 7 illustrates a plan view of an input device in accordance with embodiments.

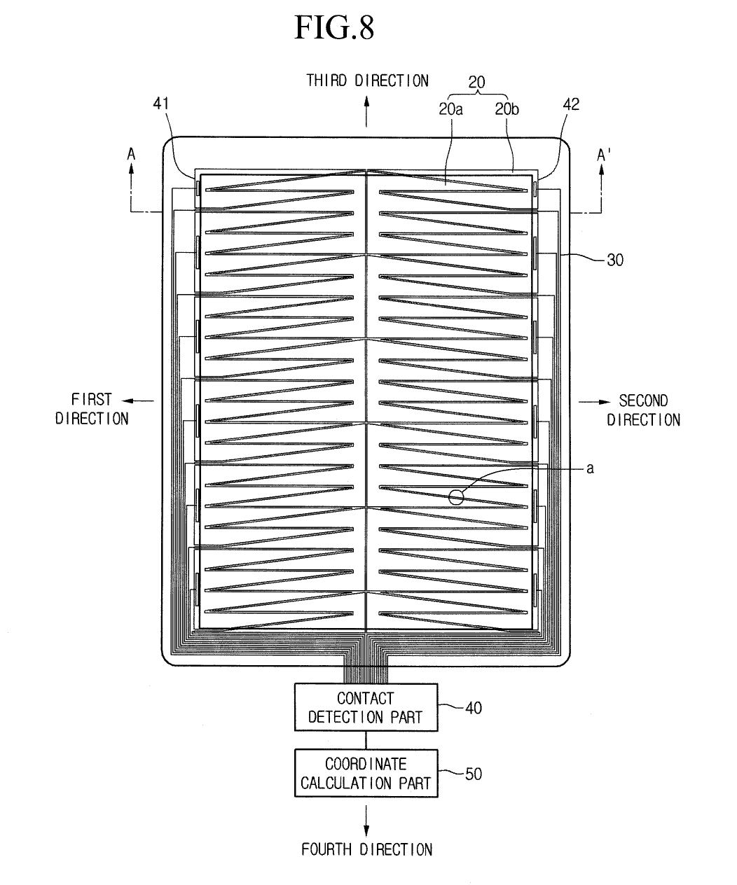

Example FIG. 8 illustrates a plan view of an input device in accordance with embodiments.

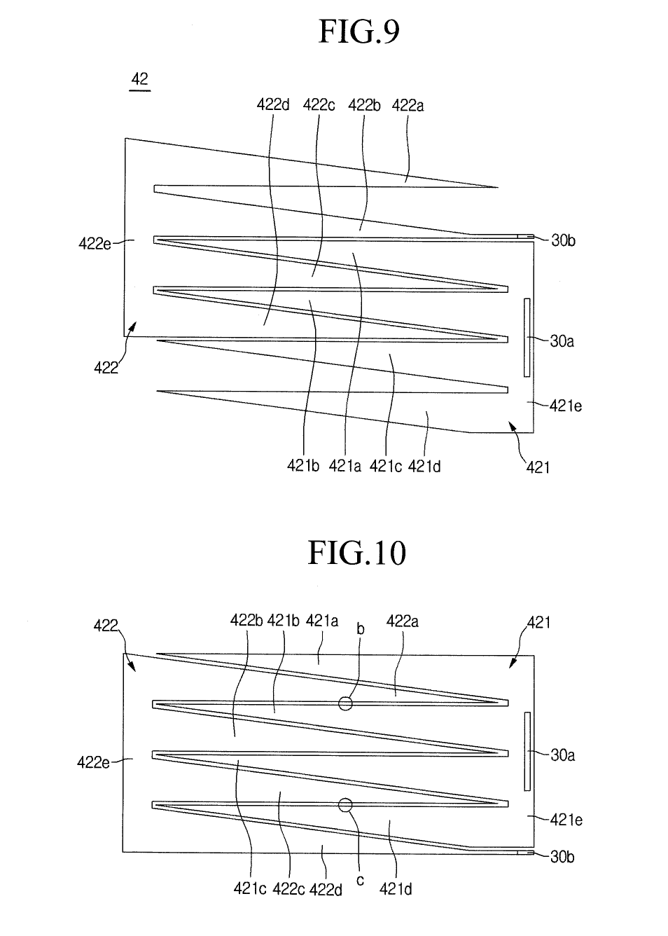

Example FIG. 9 illustrates a view of a unit electrode of a transparent electrode in the input device in accordance with embodiments.

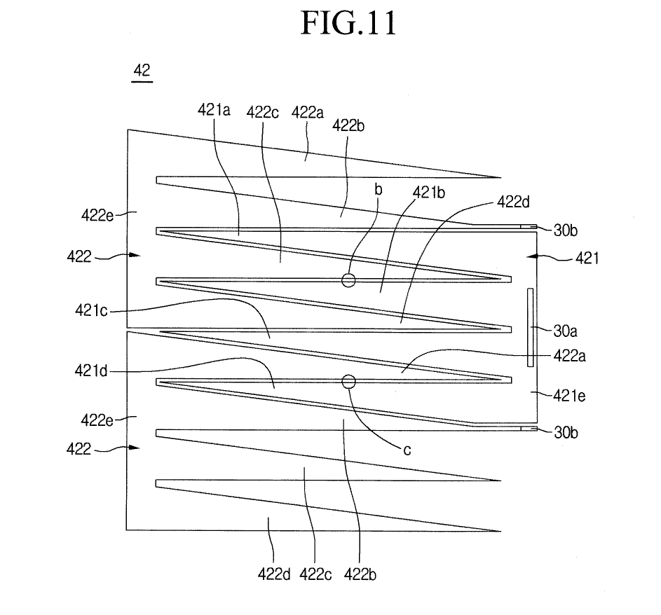

Example FIGS. 10 and 11 illustrate comparative views for explaining an effect of the input device in accordance with embodiments.

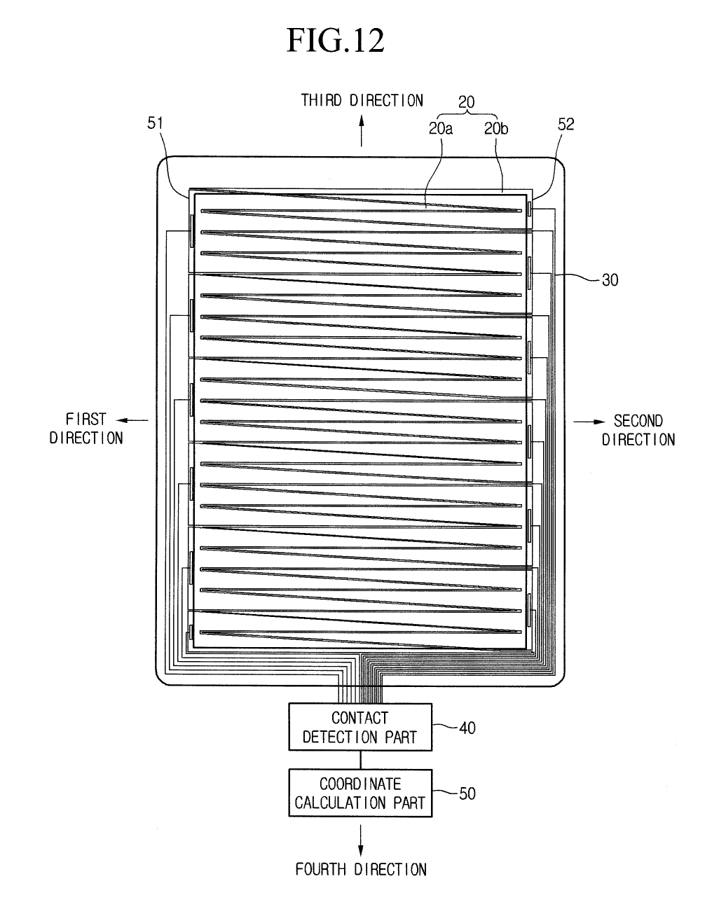

Example FIG. 12 illustrates a plan view of an input device in accordance with embodiments.

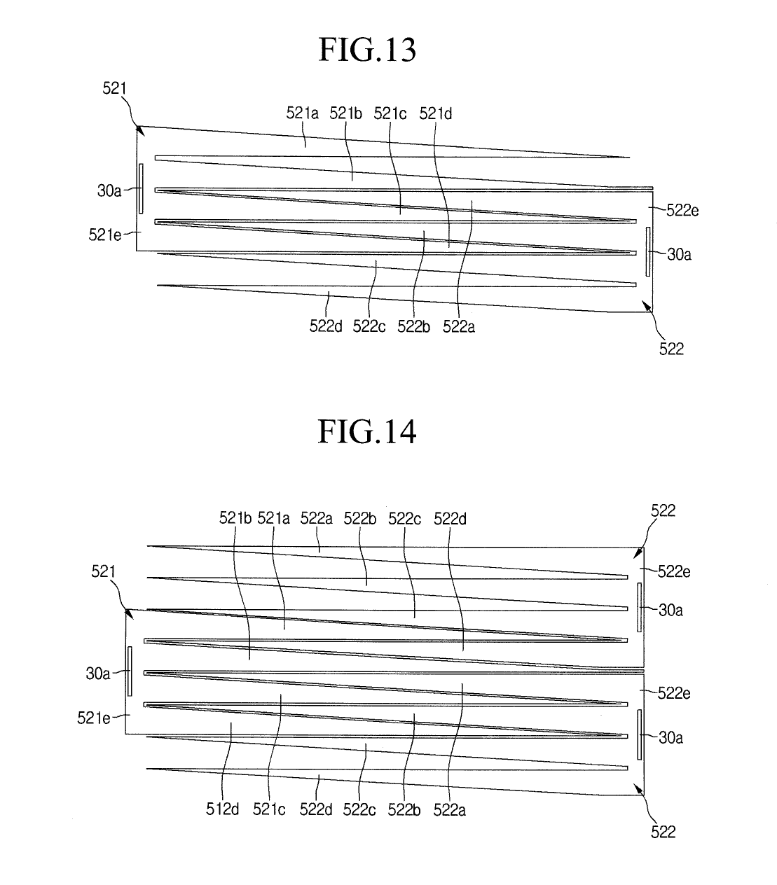

Example FIG. 13 illustrates a view of a unit electrode of a transparent electrode in the input device of example FIG. 12 in accordance with embodiments.

Example FIG. 14 illustrates a view of a configuration of the electrode in the input device in accordance with embodiments.

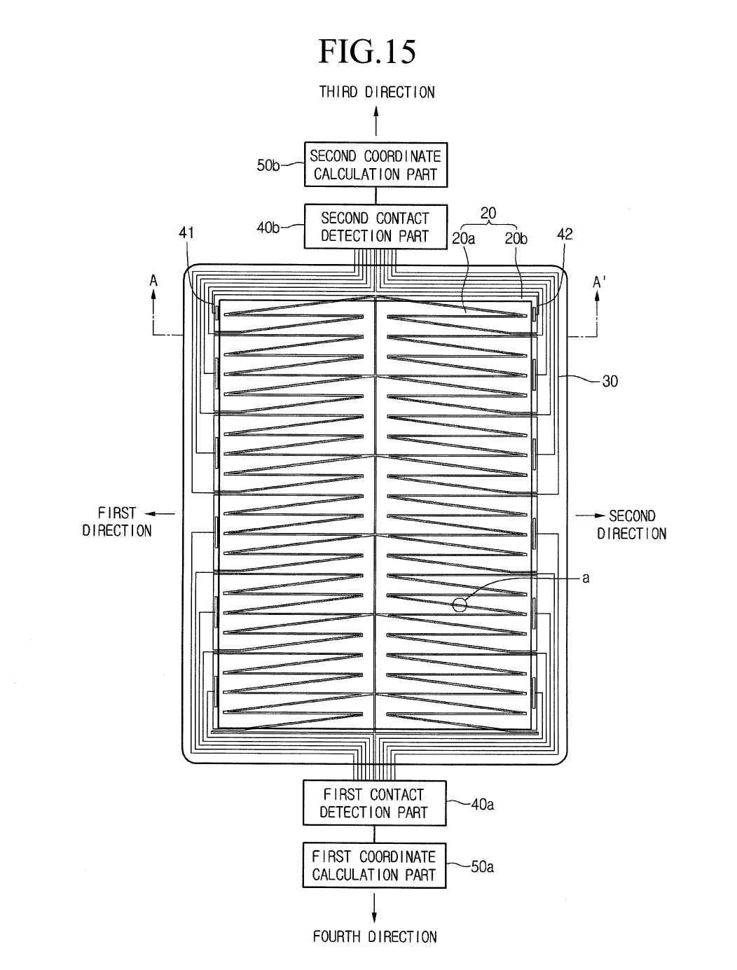

Example FIG. 15 illustrates a plan view of an input device in accordance with embodiments.

### DESCRIPTION

Reference will now be made in detail to the embodiments of the present disclosure, examples of which are illustrated in the accompanying drawings.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

A light emitting device in accordance with embodiments will be described in detail with reference to the accompanying drawings. Embodiments of the invention may, however, be embodied in many different forms and should not be construed as being limited to the embodiments set forth herein; rather, that alternate embodiments included in other retrogressive inventions or falling within the spirit and scope of the present disclosure can easily be derived through adding, altering, and changing, and will fully convey the concept of the invention to those skilled in the art.

In the descriptions of embodiments, it will be understood that when a layer (or film), a region, a pattern, or a structure is referred to as being “on/above/over/upper” board or “under/below/lower,” the “on/above/over/upper” board and “under/below/lower” include each layer (or film), a region, a pad, or patterns, which can be directly formed on board as well as each layer (or film), the region, the pad, or the patterns, which can be indirectly formed under another layer (film), another region, another pad, or another patterns, with one or more intervening layers may also being present. Therefore, meaning thereof should be judged according to the spirit of the present disclosure.

Thickness or size of each layer in the drawings has been exaggerated, omitted, or roughly illustrated for the convenience and clarity of the description. Further, sizes of the respective components do not entirely reflect actual sizes thereof.

Example FIG. 1 is a plan view of an input device in accordance with a first embodiment. Example FIG. 2 is a sectional view taken along line A-A′ of example FIG. 1. Example FIG. 3 is a view illustrating an operation principle of the input device in accordance with the first embodiment. Example FIG. 4 is a view illustrating a unit electrode of a transparent electrode in the input device in accordance with the first embodiment.

As illustrated in example FIGS. 1 and 2, an input device in accordance with a first embodiment has a structure of a capacitive touch panel. A single layer touch panel and a dual layer touch panel are widely used as the capacitive touch panel. In the single layer touch panel, transparent electrodes are disposed on and/or over the same plane. On the other hand, in the dual layer touch panel, transparent electrodes are disposed on and/or over upper and lower portions with a substrate therebetween, respectively. In case of the dual layer touch panel, a touch position may be precisely detected. However, an input device may be expensive in price and thick in thickness.

A capacitive touch panel including a single layer will be described as an example of an input device in accordance with embodiments. The capacitive touch panel including the single layer may be inexpensive in price and thin in thickness. In the capacitive touch panel, a plurality of separated electrodes and wires connected to the electrodes may be provided to detect a precise touch position. However, in case of the capacitive touch panel including the single layer, since the wires do not cross each other, the electrodes may be limited to the number and arrangement, unlike the dual layer touch panel.

The input device according to the first embodiment includes a window 20, a transparent film 15 disposed under the window 20, first and second transparent electrodes 11 and 12 respectively disposed on and/or over a plurality of areas under the transparent film 15, and a wire 30 connected to the first and second transparent electrodes 11 and 12. For example, the first transparent electrode 11 is disposed on and/or over a first area under the window 20, and the second transparent electrode 12 is disposed on and/or over a second area under the window 20.

The window 20 is disposed on and/or over a front surface of a display screen. For example, the window 20 is disposed on and/or over a front surface of the electronics such as a smart phone. The window 20 has an approximately rectangular shape. The window 20 has long sides in a first direction and a second direction opposite to the first direction and short sides in a third direction and a fourth direction opposite to the third direction. For example, as illustrated in example FIG. 1, the first direction may be a left direction, and the second direction may be a right direction. The third direction may be an upward direction, and the fourth direction may be a downward direction (corresponding to a direction in which a contact detection part 40 is disposed when viewed in example FIG. 1). For example, the first area may be disposed in the first direction with respect to a center of the window 20, and the second area may be disposed in the second direction with respect to the center of the window 20.

The window 20 may include a transparent part 20a on and/or over which the display screen is disposed and an opaque part 20b on and/or over which a pigment is deposited, printed, or coated on and/or over a portion at which the display screen is not disposed. The opaque part 20b is disposed surrounding a peripheral region of the transparent part 20a.

The window 20 may be manufactured using a transparent substrate formed of a material such as acrylic, tempered glass, or polyethylene resin having a uniform thickness and permittivity. The transparent film 15 is disposed on and/or over a back surface of the window 20 to support the first and second transparent electrodes 11 and 12 and the wire 30.

The first and second transparent electrodes 11 and 12 may be formed of a transparent conductive material such as indium tin oxide (ITO) or antimony tin oxide (ATO). Here, the transparent conductive material may be formed on and/or over one surface of the transparent film 15 and then be patterned using photolithography to manufacture the first and second transparent electrodes 11 and 12. The first and second transparent electrodes 11 and 12 may be formed of substantially the same material and have substantially the same shape. However, the transparent electrode disposed in the first direction with respect to the center of the window 20 may be called the first transparent electrode 11, and the transparent electrode spaced from the first transparent electrode 11 and disposed on and/or over the second direction may be called the second transparent electrode 12. Meaning, the first transparent electrode 11 may be disposed in the first direction with respect to a virtual straight line passing through the center of the window 20 and crossing centers of the short sides in a direction parallel to those of the long sides. The second transparent electrode 12 may be disposed in the second direction with respect to a virtual straight line passing through the center of the window 20 and crossing the centers of the short sides in the direction parallel to those of the long sides.

The first and second transparent electrodes 11 and 12 may be symmetric with respect to the center of the window 20. Meaning, the first and second transparent electrodes 11 and 12 may be symmetrically disposed with respect to the virtual straight line passing through the center of the window 20 and crossing the centers of the short sides in the direction parallel to those of the long sides.

As illustrated in example FIG. 4, the second transparent electrode 12 includes a plurality of unit electrodes. Although the unit electrodes of the second transparent electrode 12 are illustrated in example FIG. 4 as an example, each of unit electrodes of the first transparent electrode 11 may have the substantially same shape as that of each of the unit electrodes of the second transparent electrode 12 except that each of the unit electrodes of the first transparent electrode 11 has a shape symmetric with each of the unit electrodes of the second transparent electrode 12.

Each of the unit electrodes includes a first electrode 121 and a second electrode 122. The first electrode 121 and the second electrode 122 are spaced a predetermined distance from each other. The unit electrode may have a rectangular shape as a the whole.

The first electrode 121 includes at least two or more electrode parts 121a, 121b, and 121c. The at least two or more electrode parts 121a, 121b, and 121c are connected to each other by a connection part 121d. A wiring part 30a connected to the wire 30 is disposed on and/or over the connection part 121d. Each of the at least two or more electrode parts 121a, 121b, and 121c may have a triangular shape/cross-section such as a right-angled triangle or an isosceles triangle or a square shape/cross-section such as a trapezoid. For example, each of the at least two or more electrode parts 121a, 121b, and 121c may have a right-angled triangular shape/cross-section. Meaning, the first electrode 121 includes the at least two or more electrode parts 121a, 121b, and 121c and the connection part 121d connecting the at least two or more electrode parts 121a, 121b, and 121c to each other. Thus, the first electrode 121 may have a finger shape/cross-section.

The second electrode 122 and the first electrode 121 may be alternately disposed. The second electrode 122 includes at least two or more electrode parts 122a, 122b, and 122c. The at least two or more electrode parts 122a, 122b, and 122c are connected to each other by a connection part 122d. A wiring part 30b connected to the wire 30 is disposed on and/or over one electrode part 122c of the at least two or more electrode parts 122a, 122b, and 122c.

Each of the electrode parts 121a, 121b, and 121c of the first electrode 121 and the electrode parts 122a, 122b, and 122c of the second electrode 122 may have a triangular shape/cross-section. Inclined surfaces forming sides of the triangular shapes/cross-sections may face each other.

The wires are connected to the first and second electrodes 121 and 122 constituting the unit electrode in the same direction. Meaning, as illustrated in example FIG. 1, the wires 30 are connected to the first and second electrodes 121 and 122 in the second direction. The wires 30 connecting the first and second electrodes 121 and 122 to each other are disposed on layers having the same height and do not cross each other. Meaning, the wires connecting the first and second electrodes 121 and 122 to each other do not at least partially overlap each other.

The wires 30 connected to the first electrode 121 may be disposed on layers having the same height as that of the second electrode and do not cross each other. Meaning, the first electrode 121 and the wires 30 connected to the first electrode 121 do not at least partially overlap each other. The first electrode 121 and the wires 30 connected to the first electrode 121 do not at least partially overlap the wires 30 connected to the second electrode 122.

The second transparent electrode 12 includes a plurality of unit electrodes. The plurality of unit electrodes are disposed along the third direction (or the fourth direction). In the first embodiment, six unit electrodes are arranged as an example. Similarly, the first transparent electrode 11 includes a plurality of unit electrodes. The plurality of unit electrodes are disposed along the third direction (or the fourth direction). In the first embodiment, six unit electrodes are arranged as an example. A conductive metal material such as silver (Ag) may be printed on and/or over the transparent film 15 on and/or over which the first and second transparent electrodes 11 and 12 using a silk screen process to manufacture the wires 30.

The wires 30 are connected to the first transparent electrode 11 and the second transparent electrode 12, respectively. The wire 30 connected to the first transparent electrode 11 extends outside the other area contacting the first area on which the first transparent electrode 11 is disposed, e.g., an area which does not contact the second area. The wire 30 connected to the second transparent electrode 12 extends outside the other area contacting the second area on and/or over which the second transparent electrode 12 is disposed, e.g., an area which does not contact the first area. Meaning, the wire 30 connected to the first transparent electrode 11 extends toward the outside of the window 20 contacting the first transparent electrode 11. The wire 30 connected to the second transparent electrode 12 extends toward the outside of the window 20 contacting the second transparent electrode 12.

The input device in accordance with the first embodiment may further include a contact detection part 40 and a coordinate calculation part 50. The contact detection part 40 is electrically connected to the first and second transparent electrodes 11 and 12 through the wires 30 to detect a change of a capacitance generated by user' contact applied to the window 20. Meaning, as illustrated in example FIG. 3, when a portion of a user's body, e.g., an end of a finger contacts the window 20, a change of a capacitance occurs by a capacitance Ct formed in a thickness direction of the window 20 and a human body capacitor Cb connected to the capacitor Ct in series and grounded in the input device modeled as a capacitor which uses the first and second transparent electrodes 11 and 12 of a corresponding position and the contact surface of the human body as two electrode plates and also uses the window 20 and the transparent film 15 as dielectric materials. The contact detection part 40 is constituted as an electric circuit for detecting an electrical change occurring by such a capacitance.

The coordinate calculation part 50 calculates components of the first and second directions (a horizontal direction) and the third and fourth direction (a vertical direction) of the contact position based on data with respect to the change of the capacitance obtained by the contact detection part 40. The coordinate calculation part 50 may receive a signal with respect to whether the contact is performed on at least two or more positions from the contact detection part 40 to recognize multi touch. For example, the user may detect the operations of the user's two fingers due to the reorganization of the multi touch. Thus, inputs which can execute preset functions such as reduction, expansion, and rotation of the displayed screen may be detected. The coordinate calculation part 50 of the contact detection part 40 may have a structure of an integrated circuit (IC). For example, the coordinate calculation part 50 may be installed on and/or over the window 20 in a chip-on-glass (COG) type or mounted on and/or over a flexible board such as a flexible printed circuit board (FPCB).

In the input device in accordance with the first embodiment, the first transparent electrode 11 includes the plurality of unit electrodes arranged in the first direction and the second transparent electrode 12 includes the plurality of unit electrodes arranged in the second direction with respect to the virtual straight line classifying the window 20 into the first and second directions.

Each of the unit electrodes of the second transparent electrode 12 includes the first electrode 121 disposed in the second direction and the second electrode 122 disposed between the first electrode 121 and the virtual straight line. The wires 30 are connected to the first and second electrodes 121 and 122 in the second direction, respectively.

Although not shown, each of the unit electrodes of the first transparent electrode 11 includes a first electrode disposed in the first direction and a second electrode disposed between the first electrode and the virtual straight line. The wires 30 are connected to the first and second electrodes in the first direction, respectively.

The input device in accordance with the first embodiment includes the plurality of unit electrodes, and each of the unit electrodes includes the first and second electrodes. Each of the first and second electrodes includes the at least two or more electrode parts. The inclined surfaces of the electrode parts face each other.

When a portion of the user's body contacts the window 20, a capacitance may be changed at a portion at which the portion of the user's body directly contacts the window 20 as well as a portion adjacent to the portion at which the portion of the user's body directly contacts the window 20. For example, when a portion of the user's body contacts a point “a,” a capacitance may be changed at the first and second electrodes 121 and 122 of the unit electrode contacting the portion of the user's body. In addition, a capacitance may be changed at the other electrodes adjacent to the unit electrode contacting the portion of the user's body. Thus, the change of the capacitance may be detected by the contact detection part 40 and then calculated by the coordinate calculation part 50 to calculate a coordinate of the portion contacting the portion of the user's body. Specifically, each of the first and second electrodes 121 and 122 may include electrode parts 121a, 121b, 121c, 122a, 122b, and 122c. When a portion of the user's body contacts the electrode parts 121a, 121b, 121c, 122a, 122b, and 122c, since a capacitance is changed according to a change of a contact area, a contact position may be precisely detected.

When a portion of the user's body is moved in a horizontal direction (for example, moved from the first direction to the second direction) while contacting one electrode part 121a, since a contact area of the electrode part 121a is changed according to a movement course of the portion of the user's body, a user's input type may be detected.

In the input device in accordance with the first embodiment, since each of the first and second electrodes 121 and 122 includes the at least two or more electrode parts 121a, 121b, 121c, 122a, 122b, and 122c, a capacitance may be changed at the plurality of electrode parts even though a portion of the user's body contacts any position. Thus, a coordinate of the contact position may be more easily and precisely detected.

Example FIG. 5 is a plan view of an input device in accordance with a second embodiment. Example FIG. 6 is a view illustrating a unit electrode of a transparent electrode in the input device in accordance with the second embodiment.

The input device illustrated in example FIGS. 5 and 6 is the same as illustrated in example FIGS. 1 and 4 in accordance with the first embodiment except for a configuration of an electrode. Thus, descriptions duplicated with those of example FIGS. 1 to 4 will be omitted.

As illustrated in example FIGS. 5 and 6, the input device in accordance with the second embodiment includes a first transparent electrode 21 and a second transparent electrode 22. Although a unit electrode of the second transparent electrode 22 is illustrated in example FIG. 6 as an example, a unit electrode of the first transparent electrode 21 may have the substantially same shape/cross-section as that of the second transparent electrode 22 except that the unit electrode of the first transparent electrode 21 has a shape/cross-section symmetric with the unit electrode of the second transparent electrode 22.

The unit electrode includes a first electrode 221 and a second electrode 222. The second electrode 222 and the first electrode 221 may be alternately disposed. The first electrode 221 and the second electrode 222 are spaced a predetermined distance from each other. The unit electrode has a rectangular shape/cross-section on the whole.

The first electrode 221 includes two electrode parts 221a and 221b. The two electrode parts 221a and 221b are connected to each other by a connection part 221c. A wiring part 30a connected to the wire 30 is disposed on the connection part 221c. The two electrode parts 221a and 221b may have a right-angled triangular shape/cross-section and an isosceles triangular shape/cross-section, respectively.

The second electrode 222 includes two electrode parts 222a and 222b. The two electrode parts 222a and 222b are connected to each other by a connection part 222c. A wiring part 30b connected to the wire 30 is disposed on one electrode part 222b of the two electrode parts 222a and 222b.

Each of the electrode parts 221a and 221b of the first electrode 221 and the electrode parts 222a and 222b of the second electrode 222 has a triangular shape/cross-section. Inclined surfaces forming sides of the triangular shape/cross-sections face each other.

In the input device in accordance with the second embodiment, the electrode parts 221a, 221b, 222a, and 222b of the first and second electrodes 221 and 222 have vertical lengths (i.e., lengths from a third direction to a fourth direction) different from each other. Meaning, the electrode parts 221a, 221b, 222a, and 222b have right-angled triangular shape/cross-sections and isosceles triangular shape/cross-sections, respectively. Thus, when a portion of a user's body is moved in a vertical direction (for example, moved from the third direction to the fourth direction) while contacting one electrode part 221a, since a contact area of each of the electrode parts 221a and 221b is changed according to a movement course of the portion of the user's body, a user's input type may be precisely detected.

Example FIG. 7 is a plan view of an input device in accordance with a third embodiment. The input device illustrated in example FIG. 7 is equal to that of example FIGS. 1 and 4 in accordance with the first embodiment except for a configuration of an electrode. Thus, descriptions duplicated with those of example FIGS. 1 to 4 will be omitted.

As illustrated in example FIG. 7, the input device in accordance with the third embodiment includes a first transparent electrode 31 and a second transparent electrode 32. Each of the first and second transparent electrodes 31 and 32 includes a unit electrode in which two electrode parts each having an isosceles triangular shape/cross-section face each other.

Each of the first and second transparent electrodes 31 and 32 includes five unit electrodes. Each of the first and second transparent electrodes 31 and 32 includes electrodes each having a right-angled triangular shape/cross-section on ends of third and fourth directions. Meaning, each of the first and second transparent electrodes 31 and 32 may include the other electrode having a shape/cross-section different from that of the each unit electrode in at least one direction of the third and fourth directions.

Example FIG. 8 is a plan view of an input device in accordance with a fourth embodiment. Example FIG. 9 is a view illustrating a unit electrode of a transparent electrode in the input device in accordance with the fourth embodiment. Example FIGS. 10 and 11 are comparative views for explaining an effect of the input device in accordance with the fourth embodiment.

The input device illustrated in example FIGS. 8 and 9 is the same as that of example FIGS. 1 and 4 in accordance with the first embodiment except for a configuration of an electrode. Thus, descriptions duplicated with those of example FIGS. 1 to 4 will be omitted.

As illustrated in example FIGS. 8 to 11, the input device in accordance with the fourth embodiment includes a first transparent electrode 41 and a second transparent electrode 42. Although a unit electrode of the second transparent electrode 42 is illustrated in example FIG. 9 as an example, a unit electrode of the first transparent electrode 41 may have the substantially same shape/cross-section as that of the second transparent electrode 42 except that the unit electrode of the first transparent electrode 41 has a shape/cross-section symmetric with the unit electrode of the second transparent electrode 42.

The unit electrode includes a first electrode 421 and a second electrode 422. The first electrode 421 and the second electrode 422 are spaced a predetermined distance from each other and partially dislocated with each other.

The first electrode 421 includes four electrode parts 421a, 421b, 421c, and 421d. The four electrode parts 421a, 421b, 421c, and 421d are connected to one another by a connection part 421e. A wiring part 30a connected to a wire 30 is disposed on the connection part 421e. Each of the four electrode parts 421a, 421b, 421c, and 421d may have a triangular shape/cross-section such as a right-angled triangle or an isosceles triangle or a square shape/cross-section such as a trapezoid. Each of the four electrode parts 421a, 421b, 421c, and 421d protrudes from the connection part 421e in a first direction.

The three electrode parts 421a, 421b, and 421c of the four electrode parts 421a, 421b, 421c, and 421d have the same shape/cross-section. The other one electrode part 421d may have a shape/cross-section slightly different from that of each of the three electrode parts 421a, 421b, and 421c. However, the slightly different shape/cross-sections do not have a large influence on the detection of a change of a capacitance.

The second electrode 422 and the first electrode 421 are alternately disposed. The second electrode 422 includes four electrode parts 422a, 422b, 422c, and 422d. The four electrode parts 422a, 422b, 422c, and 422d are connected to one another by a connection part 422e. A wiring part 30b connected to a wire 30 is disposed on one electrode part 422b of the four electrode parts 422a, 422b, 422c, and 422d. Each of the four electrode parts 422a, 422b, 422c, and 422d protrudes from the connection part 422e in a second direction.

The three electrode parts 422a, 422c, and 422d of the four electrode parts 422a, 422b, 422c, and 422d have the same shape/cross-section. The other one electrode part 422b may have a shape/cross-section slightly different from that of each of the three electrode parts 422a, 422c, and 422d. However, the slightly different shape/cross-sections do not have a large influence on the detection of a change of a capacitance. 100761 Although each of the first and second electrodes 421 and 422 includes the four electrode parts in the fourth embodiment, each of the first and second electrodes 421 and 422 may include five or six or more electrode parts. The present disclosure is not limited to the number and shape/cross-section of the electrode part. For example, three or more electrode parts may be provided, and each of the electrode parts may have a quadrangular shape/cross-section or pentagonal shape/cross-section except for a triangular shape/cross-section or have a curved surface. Each of the electrode parts 421a, 421b, 421c, and 421d of the first electrode 421 and the electrode parts 422a, 422b, 422c, and 422d of the second electrode 422 may have a triangular shape/cross-section.

The two electrode parts 421a and 421b of the first electrode 421 face the two electrode parts 422c and 422d of the second electrode 422. The two electrode parts 421c and 421d of the first electrode 421 face the two electrode parts 422a and 422b of the other second electrode 422 adjacent to the second electrode 422. At least one electrode part 421a or 421b of the first electrode 421 is disposed between the electrode parts 422b, 422c, and 422d of the second electrode 422. At least one electrode part 421d of the first electrode 421 is disposed between the electrode parts 422a and 422b of the other second electrode 422 adjacent to the second electrode 422. At least one electrode part 421c of the first electrode 421 is disposed between the electrode part 422d of the second electrode 422 and the electrode part 422a of the other second electrode 422 adjacent to the second electrode 422.

At least one electrode part 421a or 421b of the first electrode 421 is disposed between the electrode parts 422b, 422c, and 422d of the second electrode 422. At least one electrode part 421c or 421d of the first electrode 421 is disposed outside the area between the electrodes 422b, 422c, and 422d of the second electrode 422. Meaning, in the fourth embodiment, the first and second electrodes 421 and 422 are dislocated with each other in a third or fourth direction, i.e., a vertical direction.

When the first and second electrodes 421 and 422 are dislocated with each other, the position input by the user may be more precisely detected. For example, as illustrated in example FIG. 10, when the user touches a point “b” and a point “c” in the state where the first and second electrodes 421 and 422 are not dislocated, changes of capacitances generated in the first and second electrodes 421 and 422 are not large. Thus, it may be difficult to determine whether the user touches the point “b” or the point “c.”

On the other hand, as illustrated in example FIG. 11, when the user touches the point “b” and the pint “c” in the state where the first and second electrodes 421 and 422 are dislocated, a change of a capacitance may occur at the first electrode 421 and the two electrode electrodes 422 according to the touch of the point “b” and the touch of the point “c.” Thus, the touch of the point “b” and the touch of the point “c” may be more clearly determined.

Meaning, the touch of the point “b” may be precisely detected because the capacitances generated at the electrode parts 421a and 421b of the first electrode 421 and the electrode parts 422c and 422d of the second electrode 422 of the two electrodes 421 disposed in the third direction are significantly changed. The touch of the point “c” may be precisely detected because the capacitances generated at the electrode parts 421 c and 421 d of the first electrode 421 and the electrode parts 422a and 422b of the second electrode 422 of the two electrodes 421 disposed in the fourth direction are significantly changed. Thus, in the input device of example FIGS. 8 to 11 in accordance with the fourth embodiment, the user's input may be more precisely detected.

Example FIG. 12 is a plan view of an input device in accordance with a fifth embodiment. Example FIG. 13 is a view illustrating a unit electrode of a transparent electrode in the input device of example FIG. 12 in accordance with the fifth embodiment. Example FIG. 14 is a view illustrating a configuration of the electrode in the input device in accordance with the fifth embodiment.

The input device illustrated in example FIGS. 12 and 14 in accordance with the fifth embodiment is the same as that of example FIGS. 1 and 4 in accordance with the first embodiment except for a configuration of an electrode. Thus, descriptions duplicated with those of example FIGS. 1 to 4 will be omitted. The input device illustrated in example FIGS. 12 to 14 in accordance with the fifth embodiment has the same operation principle as that of the input device illustrated in example FIGS. 8 to 11 in accordance with the fourth embodiment. Thus, descriptions duplicated with those of example FIGS. 8 to 11 will be omitted.

As illustrated in example FIGS. 12 to 14, the input device in accordance with the fifth embodiment includes a unit electrode. The unit electrode includes a first electrode 521 and a second electrode 522. The first electrode 521 and the second electrode 522 are spaced a predetermined distance from each other and partially dislocated with each other.

The first electrode 521 includes four electrode parts 521a, 521b, 521c, and 521d. Here, the four electrode parts 521a, 521b, 521c, and 521d are connected to one another by a connection part 521e. A wiring part 30a connected to a wire 30 is disposed on the connection part 521e. Each of the four electrode parts 521a, 521b, 521c, and 521d may have a triangular shape/cross-section such as a right-angled triangle or an isosceles triangle or a square shape/cross-section such as a trapezoid. For example, each of the electrode parts 521a, 521b, 521c, and 521d may have a right-angled triangular shape/cross-section. Each of the electrode parts 521a, 521b, 521c, and 521d protrudes from the connection part 521e in a second direction.

The second electrode 522 and the first electrode 521 are alternately disposed. The second electrode 522 includes four electrode parts 522a, 522b, 522c, and 522d. Here, the four electrode parts 522a, 522b, 522c, and 522d are connected to one another by a connection part 522e. A wiring part 30a connected to a wire 30 is disposed on the connection part 522e. Each of the four electrode parts 522a, 522b, 522c, and 522d protrudes from the connection part 522e in a first direction.

Although each of the first and second electrodes 521 and 522 includes the four electrode parts in the fifth embodiment, the present disclosure is not limited to the number and shape/cross-section of the electrode part. For example, at least three or more electrode parts may be provided, and each of the electrode parts may have a quadrangular shape/cross-section or pentagonal shape/cross-section except for a triangular shape/cross-section or have a curved surface. Each of the electrode parts 521a, 521b, 521c, and 521d of the first electrode 521 and the electrode parts 522a, 522b, 522c, and 522d of the second electrode 522 may have a triangular shape/cross-section. The electrode parts 521a and 521b of the first electrode 521 face the two electrode parts 522c and 522d of the second electrode 522. The two electrode parts 521c and 521d of the first electrode 521 face the two electrode parts 522a and 522b of the other second electrode 522 adjacent to the second electrode 522.

At least one electrode part 521a of the first electrode 521 is disposed between the electrode parts 522c and 522d of the second electrode 522. At least one electrode part 521c or 521d of the first electrode 521 is disposed among the electrode parts 522a, 522b, and 522c of the other second electrode 522 adjacent to the second electrode 522. At least one electrode part 521b of the first electrode 521 is disposed between the electrode part 522d of the second electrode 522 and the electrode part 522a of the other second electrode 522 adjacent to the second electrode 522.

At least one electrode part 521a of the first electrode 521 is disposed between the electrode parts 522c and 522d of the second electrode 522. At least one electrode part 521b, 521c, or 521d of the first electrode 521 is disposed outside the area between the electrode parts 522c and 522d of the second electrode 522. Meaning, in the fifth embodiment, the first and second electrodes 521 and 522 are dislocated with each other in a third or fourth direction, i.e., a vertical direction. When the first and second electrodes 521 and 522 are dislocated with each other, the position inputted by the user may be more precisely detected.

In the input device in accordance with the fifth embodiment, unlike the input device in accordance with the fourth embodiment, a wiring part 30a connected to a wire 30 is disposed only on connection parts 521e and 522e. Unlike the input device in accordance with the fourth embodiment, the input device in accordance with the fifth embodiment does not include first and second transparent electrodes respectively disposed in first and second directions with respect to a virtual line parallel to long sides. The first and second electrodes 521 and 522 are lengthily disposed in the first or second direction.

Thus, in the input device of example FIGS. 12 to 14 in accordance with the fifth embodiment, the user's input may be more precisely detected. In addition, the wire 30 and the wiring part 30a may be more easily manufactured.

Example FIG. 15 is a plan view of an input device in accordance with a sixth embodiment. The input device illustrated in example FIG. 15 in accordance with the sixth embodiment is the same as that of example FIG. 8 in accordance with the fourth embodiment except for constructions of a wire, a contact detection part, and a coordinate calculation part. Thus, descriptions duplicated with those of the fourth embodiment will be omitted.

The input device in accordance with the sixth embodiment includes a first contact detection part 40a, a first coordinate calculation part 50a, a second contact detection part 40b, and a second coordinate calculation part 59b. The first contact detection part 40a and the first coordinate calculation part 50a detect signals of the electrodes disposed in the fourth direction among the electrodes of the first and second transparent electrodes 41 and 42. The second contact detection part 40b and the second coordinate calculation part 50b detect signals of the electrodes of the first and second transparent electrodes 41 and 42 disposed in the third direction.

As described above, since the two contact detection parts and the coordinate calculation parts are provided, the detected signals may be more quickly and effectively processed.

The structure including the two contact detection part and coordinate calculation parts described in example FIG. 15 may be equally applied to other embodiments different from the above-described embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An input device comprising:
a window;
a transparent electrode disposed under the window at a plurality of areas, the transparent electrode including a first electrode and a second electrode, each of the first electrode and the second electrode having at least two electrode parts and a connection part connecting the at least two electrode parts to each other, and at least one electrode part of the first electrode being disposed between the at least two electrode parts of the second electrode; and
a wire connected to the transparent electrode via the first electrode and the second electrode to extend outside a first area which does not contact a second area which contacts a third area on which the transparent electrode is disposed.

2. The input device of claim 1, wherein the window has a square circumferential cross-section.

3. The input device of claim 1, wherein the transparent electrode comprises a first transparent electrode at a fourth area and a second transparent electrode at a fifth area which contacts the fourth area.

4. The input device of claim 3, wherein:
the wire connected to each of the first electrode and the second electrode of the first transparent electrode extends in a first direction; and
the wire connected to each of the first electrode and the second electrode of the second transparent electrode extends in a second direction.

5. The input device of claim 1, wherein the wire connected to each of the first electrode and the second electrode of the transparent electrode extends in the same direction.

6. The input device according to claim 1, wherein the wires connected to the transparent electrodes respectively disposed on the plurality of areas do not overlap each other.

7. The input device of claim 1, wherein:
each of the first electrode and the second electrode comprises an inclined surface; and
the inclined surface of the first electrode faces the inclined surface of the second electrode.

8. The input device of claim 1, wherein each of the electrode parts has a cross-section of at least one of an isosceles triangle and a right-angled triangle.

9. The input device of claim 1, wherein each of the electrode parts has cross-section of at least one of a triangle and a trapezoid.

10. The input device of claim 1, further comprising:
a contact detection part connected to the wire and configured to detect a user's contact; and
a coordinate calculation part configured to calculate a coordinate of a contact position according to a signal supplied from the contact detection part.

11. The input device of claim 10, wherein the coordinate calculation part is configured to detect signals with respect to the user's contact on at least two positions from the contact detection part to recognize multiple touches by the user.

12. The input device of claim 10, wherein:
the contact detection part comprises a first contact detection part and a second contact detection part which are respectively connected to the transparent electrodes differently from each other; and
the coordinate calculation part comprises a first coordinate calculation part and a second coordinate calculation part.

13. The input device of claim 1, wherein the transparent electrodes respectively disposed on the plurality of areas are flush with each other to realize a single layer.

14. The input device of claim 1, further comprising a transparent film between the window and the transparent electrode.

15. The input device of claim 1, wherein the first electrode and the second electrode are dislocated from each other.

16. An input device comprising:
a window;
a transparent electrode disposed under the window at a plurality of areas, the transparent electrode including a first electrode and a second electrode, each of the first electrode and the second electrode having at least three electrode parts and a connection part connecting the at least three electrode parts to one another, at least one electrode part of the first electrode being disposed between the electrodes parts of the second electrode, and at least two electrode parts of the first electrode being disposed outside an area between the electrode parts of the second electrode; and
a wire connected to the transparent electrode at each of the first electrode and the second electrode to extend outside a first area which does not contact a second area which contacts a third area on which the transparent electrode is disposed.

17. The input device of claim 16, wherein at least one of the at least two electrode parts of the first electrode is disposed between the electrode parts of another electrode part adjacent to the second electrode.

18. The input device of claim 16, further comprising:
a contact detection part connected to the wire and configured to detect a user's contact; and
a coordinate calculation part configured to calculate a coordinate of a contact position according to a signal supplied from the contact detection part.

19. An input device comprising:
a window defined by longitudinally extending sides in a first direction and a second direction which is opposite to the first direction and laterally extending sides in a third direction and a fourth direction which is opposite to the third direction;
a first transparent electrode under the window, the first transparent electrode including a plurality of unit transparent electrodes in the first direction with respect to a virtual line parallel to the longitudinally extending sides;
a second transparent electrode under the window, the second transparent electrode including a plurality of unit transparent electrodes in the second direction with respect to the virtual line parallel to the longitudinally extending sides; and
a wire connected to each of the first transparent electrode and the second transparent electrode,
wherein:
each of the unit transparent electrodes of the first transparent electrode includes a first electrode in the first direction and a second electrode between the first electrode and the second transparent electrode, the first electrode and the second electrode being dislocated from each other in one of the third direction and the fourth direction; and
each of the unit transparent electrodes of the second transparent electrode includes a third electrode in the second direction and a fourth electrode between the third electrode and the first transparent electrode, the first electrode and the second electrode being dislocated from each other in one of the third direction and the fourth direction.

20. The input device of claim 19, wherein:
the first transparent electrode is connected to the wire in the first direction;
the second transparent electrode is connected to the wire in the second direction; and
the wire is provided in plurality to allow the first transparent electrode and the second transparent electrode to be individually connected thereto and the plurality of wires do not overlap each other.
